(19) United States
(12) Patent Application Publication
(10) Pub. No.: US 2019/0237247 A1
(43) Pub. Date: Aug. 1, 2019

(54) SUBSTRATE MODULE

(71) Applicant: Murata Manufacturing Co., Ltd., Nagaokakyo-shi (JP)

(72) Inventors: Jyunichi NANJYO, Nagaokakyo-shi (JP); Narimichi MAKINO, Nagaokakyo-shi (JP)

(21) Appl. No.: 16/377,325

(22) Filed: Apr. 8, 2019

Related U.S. Application Data
(63) Continuation of application No. PCT/JP2017/038603, filed on Oct. 26, 2017.

(30) Foreign Application Priority Data
Nov. 11, 2016 (JP) 2016-220100

(51) Int. Cl. H01F 27/29; H01L 23/14; H05K 1/16; H01F 17/00

(52) U.S. Cl. CPC H01F 27/292; H01F 17/0013; H05K 1/16; H01L 23/14

(57) ABSTRACT

A ferrite substrate includes first and second magnetic material layers and first and second nonmagnetic material layers sandwiching the magnetic material layers therebetween. A surface of the first nonmagnetic material layer on an opposite side to the second magnetic material layer is a second main surface of the ferrite substrate. The first nonmagnetic material layer includes a first recess, a second recess, and a wiring conductor. The first recess is open to the second main surface and a first side, and includes a non-linear inner wall surface in a plan view. The wiring conductor is exposed to the inner wall surface of the first recess. An outer surface conductor on the inner wall surface of the first recess is connected to the wiring conductor.

### CROSS REFERENCE TO RELATED APPLICATIONS

This application claims the benefit of priority to Japanese Patent Application No. 2016-220100 filed on Nov. 11, 2016 and is a Continuation Application of PCT Application No. PCT/JP2017/038603 filed on Oct. 26, 2017. The entire contents of each application are hereby incorporated herein by reference.

### BACKGROUND OF THE INVENTION

### 1. Field of the Invention

The present invention relates to a substrate module including a substrate inside which a coil conductor is provided, and an electronic component mounted on a first main surface of the substrate.

### 2. Description of the Related Art

Various types of modules including a substrate and a mounting type electronic component have been proposed. For example, a module disclosed in Japanese Patent No. 5402482 includes a dielectric substrate and a mounting type electronic component. The mounting type electronic component is mounted on a surface of the dielectric substrate. The surface side of the dielectric substrate is covered with a sealing member. A side surface of the dielectric substrate, and a side surface and a surface (a surface on the opposite side to the dielectric substrate) of the sealing member are covered with a metal film. The dielectric substrate includes a plurality of electrodes exposed from the side surface. These electrodes are connected to the metal film.

A component built-in module disclosed in Japanese Unexamined Patent Application Publication No. 2009-4584 includes a multilayer body, a built-in type electronic component, and a mounting type electronic component. The built-in type component is incorporated in the multilayer body. The mounting type electronic component is mounted on a surface of the multilayer body. The surface side of the multilayer body is covered with a sealing member. A side surface of the multilayer body, and a side surface and a surface (a surface on the opposite side to the multilayer body) of the sealing member are covered with a metal film. In the multilayer body, an electrode exposed to the side surface and an inner via having a semicircular shape in a plan view are formed. The electrode exposed to the side surface and the inner via formed in a semicircular shape are connected to the metal film.

However, in a case where the structure described in Japanese Patent No. 5402482 is applied to a ferrite substrate, an electrode pattern exposed from the side surface and connected to the metal film is formed inside the ferrite substrate. In this case, parasitic inductance due to the electrode pattern is generated between the metal film and a reference potential (ground potential), so that the metal film cannot obtain a stable reference potential (ground potential).

Meanwhile, in a case where the structure described in Japanese Unexamined Patent Application Publication No. 2009-4584 is applied to a ferrite substrate, and a position of the inner via in a thickness direction of the ferrite substrate overlaps with a position of a coil conductor pattern in the thickness direction, the following problems arise.

In the case where miniaturization is prioritized without increasing the shape of the multilayer body, it is necessary to reduce the width of the coil conductor pattern or to reduce an opening area of a spiral coil formed by the coil conductor pattern. This degrades the characteristics of the coil. On the other hand, in the case where the characteristics of the coil are prioritized, a plane area of the multilayer body becomes larger by a size of a region where the inner via is formed, resulting in an increase in size of the multilayer body.

### SUMMARY OF THE INVENTION

Accordingly, preferred embodiments of the present invention provide substrate modules that are small in size and excellent in electrical characteristics including coil characteristics, ground characteristics, and the like.

A substrate module according to a preferred embodiment of the present invention includes a substrate, an electronic component, and an outer surface conductor. The substrate includes a first main surface and a second main surface opposing each other, and a side surface connecting the first main surface and the second main surface, and includes a component mounting land conductor on the first main surface and a terminal conductor on the second main surface. The electronic component is a surface mount component and is mounted on the component mounting land conductor. The outer surface conductor covers the first main surface side and the side surface of the substrate.

The substrate includes a magnetic material layer in which a coil is provided, and a first nonmagnetic material layer and a second nonmagnetic material layer that sandwich the magnetic material layer therebetween. A surface of the first nonmagnetic material layer on the opposite side to the magnetic material layer is the first main surface of the substrate, and a surface of the second nonmagnetic material layer on the opposite side to the magnetic material layer is the second main surface of the substrate.

Further, the substrate includes a second main surface side recess and a second main surface side wiring conductor. The second main surface side recess is open to the second main surface and the side surface, and includes a non-linear inner wall surface when viewed in a direction orthogonal to the second main surface. The second main surface side wiring conductor is provided in or on the second nonmagnetic material layer. The second main surface side wiring conductor is connected to the terminal conductor, and is exposed to the inner wall surface of the second main surface side recess. The outer surface conductor is provided on the inner wall surface of the second main surface side recess, and is connected to the second main surface side wiring conductor.

In this structure, a connection area between the second main surface side wiring conductor and the outer surface conductor is increased, so that the connection resistance between the terminal conductor and the outer surface conductor connected by the second main surface side wiring conductor decreases. Therefore, for example, in the case where the terminal conductor connected to the outer surface conductor establishes a reference potential, the reference potential (e.g., the ground potential) of the outer surface conductor is stabilized. In other words, the reference potential for the electronic component mounted on the first main surface side of the substrate is stabilized.

The substrate preferably includes a first main surface side recess and a first main surface side wiring conductor. The first main surface side recess is open to the first main surface and the side surface, and includes a non-linear inner wall surface when viewed in a direction orthogonal to the first main surface. The first main surface side wiring conductor is provided in or on the first nonmagnetic material layer. The first main surface side wiring conductor is connected to the component mounting land conductor, and is exposed to the inner wall surface of the first main surface side recess. The outer surface conductor is provided on the inner wall surface of the first main surface side recess, and is connected to the first main surface side wiring conductor.

With this structure, a connection area between the first main surface side wiring conductor and the outer surface conductor is increased, and the reference potential for the electronic component mounted on the first main surface side of the substrate is further stabilized.

It is preferable that a coefficient of linear expansion of the second nonmagnetic material layer is smaller than that of the magnetic material layer.

With this structure, a bending strength of the substrate is enhanced.

It is preferable that the second main surface side wiring conductor is disposed at an interface between the second nonmagnetic material layer and the magnetic material layer.

With this structure, due to the ductility of the second main surface side wiring conductor, the stress due to a difference in coefficient of linear expansion between the magnetic material layer and the second nonmagnetic material layer is alleviated, so that the generation of a crack is reduced or prevented.

Further, it is preferable that a substrate module according to a preferred embodiment of the present invention includes a wiring auxiliary conductor that is connected to an end portion of the second main surface side wiring conductor exposed to the inner wall surface and has a predetermined length in a thickness direction of the substrate.

With this structure, a connection area between the outer surface conductor and a conductor pattern in the substrate on the inner wall surface increases.

It is preferable that the second main surface side wiring conductor includes a first portion including an end portion on a side connected to the terminal conductor, and a second portion exposed to the inner wall surface of the second main surface side recess. The second portion is less ductile than the first portion.

With this structure, in a case where a mother multilayer body in which a plurality of substrate modules is integrally formed is divided into individual substrate modules, a dividing property is improved.

In addition, it is preferable that the first portion be made of a material containing Ag as a main ingredient, and the second portion be made of a material in which an additive is added to a material containing Ag as a main ingredient.

In this structure, a specific example of the material of the second main surface side wiring conductor is indicated, and by making the first portion and the second portion have such a composition, the ductility and the dividing property of the second main surface side wiring conductor described above are able to be easily achieved.

Moreover, it is preferable for a coefficient of linear expansion of the additive to be equal to or smaller than a coefficient of linear expansion of a material of the substrate.

In this structure, the cracking described above is able to be reduced or prevented more effectively.

It is preferable for the melting point of the additive to be higher than the melting point of Ag.

With this structure, the improved dividing property is achieved with ease.

A substrate module according to a preferred embodiment of the present invention may have the following structure. The substrate module includes the substrate, the electronic component, and the outer surface conductor having the above-described structure. The substrate module includes a first main surface side recess and a first main surface side wiring conductor. The first main surface side recess is open to the first main surface and the side surface of the substrate, and includes a non-linear inner wall surface when viewed in a direction orthogonal to the first main surface. The first main surface side wiring conductor is provided in or on the first nonmagnetic material layer, is connected to the component mounting land conductor, and is exposed to the inner wall surface of the first main surface side recess. The outer surface conductor is provided on the inner wall surface of the first main surface side recess, and is connected to the first main surface side wiring conductor.

With this structure, a connection area between the first main surface side wiring conductor and the outer surface conductor is increased, and a reference potential for the electronic component mounted on the first main surface side of the substrate is stabilized.

It is preferable that a coefficient of linear expansion of the first nonmagnetic material layer is smaller than that of the magnetic material layer.

With this structure, bending strength of the substrate is enhanced.

It is preferable that the first main surface side wiring conductor is disposed at an interface between the first nonmagnetic material layer and the magnetic material layer.

In this structure, due to the ductility of the first main surface side wiring conductor, the generation of a crack caused by a difference in coefficient of linear expansion between the magnetic material layer and the first nonmagnetic material layer is reduced or prevented.

Further, it is preferable that a substrate module according to a preferred embodiment of the present invention includes a wiring auxiliary conductor that is connected to an end portion of the first main surface side wiring conductor exposed to the inner wall surface and has a predetermined length in a thickness direction of the substrate.

With this structure, a connection area between the outer surface conductor and a conductor pattern in the substrate on the inner wall surface increases.

It is preferable that the first main surface side wiring conductor includes a third portion including an end portion on a side connected to the component mounting land conductor and a fourth portion exposed to the inner wall surface of the first main surface side recess. The fourth portion is less ductile than the third portion.

With this structure, in a case where a mother multilayer body in which a plurality of substrate modules is integrally formed is divided into individual substrate modules, a dividing property is improved.

In addition, it is preferable that the third portion be made of a material containing Ag as a main ingredient, and the fourth portion be made of a material in which an additive is added to a material containing Ag as a main ingredient.

In this structure, a specific example of the material of the first main surface side wiring conductor is indicated, and by making the third portion and the fourth portion to have the composition described above, the ductility and the dividing property of the first main surface side wiring conductor described above is able to be easily achieved.

Moreover, it is preferable for a coefficient of linear expansion of the additive to be equal to or smaller than a coefficient of linear expansion of a material of the substrate.

In this structure, the cracking described above is able to be reduced or prevented more effectively.

It is preferable for the melting point of the additive to be higher than the melting point of Ag.

With this structure, the improved dividing property is easily achieved.

According to the present invention, it is possible to achieve a substrate module excellent in electrical characteristics and small in size.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a side cross-sectional view illustrating a schematic configuration of a ferrite substrate module according to a first preferred embodiment of the present invention.

FIG. 2 is an enlarged perspective view of a recess of the ferrite substrate module according to the first preferred embodiment of the present invention.

FIG. 3 is a schematic circuit diagram illustrating an example of a power supply circuit to which the ferrite substrate module according to the first preferred embodiment of the present invention is applied.

FIG. 4 is a flowchart illustrating a manufacturing method for the ferrite substrate module according to the first preferred embodiment of the present invention.

FIGS. 5A to 5C are side cross-sectional views each illustrating a structure in a manufacturing process.

FIGS. 6A and 6B are side cross-sectional views each illustrating a structure in a manufacturing process, and FIGS. 6C and 6D are plan cross-sectional views in each of which a recess is enlarged and illustrated in a state of a mother multilayer body.

FIG. 7 is an enlarged perspective view illustrating a recess of a second example of a ferrite substrate module according to a preferred embodiment of the present invention.

FIG. 8 is an enlarged perspective view illustrating a recess of a third example of a ferrite substrate module according to a preferred embodiment of the present invention.

FIG. 9 is an enlarged perspective view illustrating a recess of a fourth example of a ferrite substrate module according to a preferred embodiment of the present invention.

FIG. 10 is a side cross-sectional view illustrating a schematic configuration of a ferrite substrate module according to a second preferred embodiment of the present invention.

FIG. 11 is an enlarged perspective view of a recess of the ferrite substrate module according to the second preferred embodiment of the present invention.

FIGS. 12A to 12C are side cross-sectional views each illustrating a structure in a manufacturing process, and FIG. 12D is a plan cross-sectional view in which a recess is enlarged and illustrated in a state of a mother multilayer body.

FIG. 13 is a side cross-sectional view illustrating a schematic configuration of a ferrite substrate module according to a third preferred embodiment of the present invention.

FIG. 14 is a side cross-sectional view illustrating a schematic configuration of a ferrite substrate module according to a fourth preferred embodiment of the present invention.

FIGS. 15A and 15B are side cross-sectional views each illustrating a structure in a manufacturing process.

### DETAILED DESCRIPTION OF THE PREFERRED EMBODIMENTS

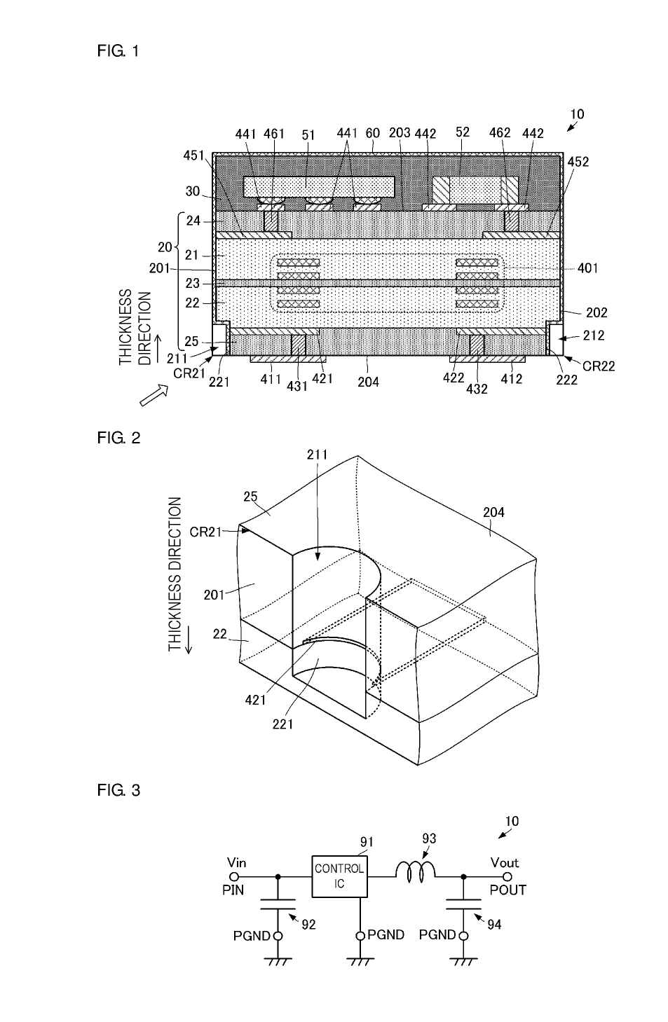

A ferrite substrate module according to a first preferred embodiment of the present invention will be described with reference to the accompanying drawings. FIG. 1 is a side cross-sectional view illustrating a schematic configuration of the ferrite substrate module according to the first preferred embodiment of the present invention. FIG. 2 is an enlarged perspective view of a recess of the ferrite substrate module according to the first preferred embodiment of the present invention. FIG. 2 is an enlarged perspective view in a direction of a thick arrow in FIG. 1. FIG. 3 is a schematic circuit diagram illustrating an example of a power supply circuit to which the ferrite substrate module according to the first preferred embodiment of the present invention is applied.

As illustrated in FIG. 1, a ferrite substrate module 10 includes a ferrite substrate 20, a sealing resin 30, electronic components 51 and 52, and an outer surface conductor 60.

The ferrite substrate 20 has a rectangular shape in a plan view, in other words, has a rectangular parallelepiped shape, for example. To rephrase, the ferrite substrate 20 includes a first main surface 203 and a second main surface 204 opposing each other, and further includes a first side surface 201 and a second side surface 202 connecting the first main surface 203 and the second main surface 204.

The ferrite substrate 20 includes magnetic material layers 21 and 22, and nonmagnetic material layers 23, 24, and 25. Although the nonmagnetic material layer 23 can be omitted, DC superposition characteristics of a coil can be improved by the nonmagnetic material layer 23 being provided.

The magnetic material layers 21 and 22 correspond to a “magnetic material layer”, the nonmagnetic material layer 24 corresponds to a “first nonmagnetic material layer”, and the nonmagnetic material layer 25 corresponds to a “second nonmagnetic material layer”.

The magnetic material layer 21 and the magnetic material layer 22 are laminated with the nonmagnetic material layer 23 interposed therebetween. The nonmagnetic material layer 24 is in contact with a surface of the magnetic material layer 21 on the opposite side to a contact surface thereof with respect to the nonmagnetic material layer 23. The nonmagnetic material layer 25 is in contact with a surface of the magnetic material layer 22 on the opposite side to a contact surface thereof with respect to the nonmagnetic material layer 23. In other words, in the ferrite substrate 20, the nonmagnetic material layer 24, the magnetic material layer 21, the nonmagnetic material layer 23, the magnetic material layer 22, and the nonmagnetic material layer 25 are laminated in that order along the thickness direction.

In this structure, an outer surface of the ferrite substrate 20 on the nonmagnetic material layer 24 side (a surface orthogonal to the thickness direction) is a first main surface 203 of the ferrite substrate 20, and an outer surface of the ferrite substrate 20 on the nonmagnetic material layer 25 side (a surface orthogonal to the thickness direction) is a second main surface 204 of the ferrite substrate 20.

A first recess 211 and a second recess 212 are provided in the ferrite substrate 20. The first recess 211 and the second recess 212 correspond to a “second main surface side recess”.

As illustrated in FIGS. 1 and 2, the first recess 211 preferably is recessed from both the second main surface 204 and the first side surface 201 of the ferrite substrate 20, and is also preferably structured such that a portion of an edge CR21 where the second main surface 204 and the first side surface 201 of the ferrite substrate 20 are connected is cut out. As illustrated in FIG. 2, the first recess 211 extends through the nonmagnetic material layer 25 in the thickness direction of the ferrite substrate 20, causing the magnetic material layer 22 to be recessed by a predetermined depth from a surface on the nonmagnetic material layer 25 side of the magnetic material layer 22. Further, as illustrated in FIG. 2, an inner wall surface 221 of the first recess 211 orthogonal to the second main surface 204 is non-linear. In other words, the first recess 211 is open to the second main surface 204 and the first side surface 201 of the ferrite substrate 20, and includes the non-linear inner wall surface 221 when viewed in a direction orthogonal to the second main surface 204. To be specific, in an example of FIG. 2, the inner wall surface 221 is a curved surface with a predetermined diameter.

The second recess 212 preferably is recessed from both the second main surface 204 and the second side surface 202 of the ferrite substrate 20, and is also structured such that a portion of an edge CR22 where the second main surface 204 and the second side surface 202 of the ferrite substrate 20 intersect with each other is cut out. The shape of the second recess 212 is the same as that of the first recess 211, that is, the second recess 212 extends through the nonmagnetic material layer 25 in the thickness direction of the ferrite substrate 20, causing the magnetic material layer 22 to be recessed by a predetermined depth from the surface on the nonmagnetic material layer 25 side of the magnetic material layer 22. Further, an inner wall surface 222 of the second recess 212 orthogonal to the second main surface 204 is non-linear. In other words, the second recess 212 is open to the second main surface 204 and the second side surface 202 of the ferrite substrate 20, and has the non-linear inner wall surface 222 when viewed in the direction orthogonal to the second main surface 204. To be specific, the inner wall surface 222 is a curved surface with a predetermined diameter.

A coil 401 is provided in a multilayer section including the magnetic material layers 21, 22 and the nonmagnetic material layer 23. The coil 401 includes a plurality of coil conductors and a plurality of interlayer connecting conductors. The coil conductor preferably has a winding shape, in other words, preferably has an annular shape in which a portion of its circumferential portion is cut out. The plurality of coil conductors are located at different positions in the thickness direction of the magnetic material layers 21 and 22 of the ferrite substrate 20, and the plurality of coil conductors are connected to each other with interlayer connecting conductors (not illustrated) provided in the magnetic material layers 21, 22 and the nonmagnetic material layer 23, so as to be a single conductor. With this structure, the coil 401 is implemented as a spiral conductor including a cavity at the center or approximate center in a plan view of the ferrite substrate 20 while taking the thickness direction as an axial direction.

In or on the nonmagnetic material layer 24, component mounting land conductors 441 and 442, wiring conductors 451 and 452, and interlayer connecting conductors 461 and 462 are provided. The wiring conductors 451 and 452 correspond to a “first main surface side wiring conductor”.

The component mounting land conductors 441 and 442 are provided on a surface of the nonmagnetic material layer 24 on the opposite side to a contact surface thereof with respect to the magnetic material layer 21. In other words, the component mounting land conductors 441 and 442 are provided on the first main surface 203 of the ferrite substrate 20. The electronic component 51 is a surface mount electronic component and is mounted on the component mounting land conductor 441. The electronic component 52 is a surface mount electronic component and is mounted on the component mounting land conductor 442.

The wiring conductor 451 is located at an interface between the nonmagnetic material layer 24 and the magnetic material layer 21. The vicinity of one end of the wiring conductor 451 is connected to the component mounting land conductor 441 with the interlayer connecting conductor 461 interposed therebetween. The other end of the wiring conductor 451 is exposed to the first side surface 201 of the ferrite substrate 20. In other words, an end surface of the other end of the wiring conductor 451 is flush with the first side surface 201 of the ferrite substrate 20.

The wiring conductor 452 is located at the interface between the nonmagnetic material layer 24 and the magnetic material layer 21. The vicinity of one end of the wiring conductor 452 is connected to the component mounting land conductor 442 with the interlayer connecting conductor 462 interposed therebetween. The other end of the wiring conductor 452 is exposed to the second side surface 202 of the ferrite substrate 20. In other words, an end surface of the other end of the wiring conductor 452 is flush with the second side surface 202 of the ferrite substrate 20.

Terminal conductors 411 and 412, wiring conductors 421 and 422, and interlayer connecting conductors 431 and 432 are provided in or on the nonmagnetic material layer 25. The wiring conductors 421 and 422 correspond to a “second main surface side wiring conductor”.

The terminal conductors 411 and 412 are provided on a surface of the nonmagnetic material layer 25 on the opposite side to a contact surface thereof with respect to the magnetic material layer 22. In other words, the terminal conductors 411 and 412 are provided on the second main surface 204 of the ferrite substrate 20. The terminal conductors 411 and 412 are terminal conductors for a reference potential, that is, terminal conductors for ground, for example.

The wiring conductor 421 is located at an interface between the nonmagnetic material layer 25 and the magnetic material layer 22. The vicinity of one end of the wiring conductor 421 is connected to the terminal conductor 411 with the interlayer connecting conductor 431 interposed therebetween. The other end of the wiring conductor 421 is exposed to the curved surface of the inner wall surface 221 of the recess 211. In other words, an end surface of the other end of the wiring conductor 421 has a shape along the curved surface. With this structure, an area of the end surface of the other end of the wiring conductor 421 becomes large in comparison with an example in which the end surface of the wiring conductor 421 is flush with the first side surface 201.

The wiring conductor 422 is located at the interface between the nonmagnetic material layer 25 and the magnetic material layer 22. The vicinity of one end of the wiring conductor 422 is connected to the terminal conductor 412 with the interlayer connecting conductor 432 interposed therebetween. The other end of the wiring conductor 422 is exposed to the curved surface of the inner wall surface 222 of the recess 212. In other words, an end surface of the other end of the wiring conductor 422 has a shape along the curved surface. With this structure, an area of the end surface of the other end of the wiring conductor 422 becomes large in comparison with an example in which the end surface of the wiring conductor 422 is flush with the second side surface 202.

The sealing resin 30 covers the first main surface 203 of the ferrite substrate 20 and the electronic components 51, 52.

The outer surface conductor 60 covers a surface of the sealing resin 30 on the opposite side to a surface thereof in contact with the ferrite substrate 20 (a surface as the ferrite substrate module 10), a side surface of the sealing resin 30, and the surfaces including the first side surface 201 and the second side surface 202 of the ferrite substrate 20. In this case, the outer surface conductor 60 covers the inner wall surface 221 of the first recess 211 and the inner wall surface 222 of the second recess 212.

With this structure, the wiring conductors 421 and 422 and the wiring conductors 451 and 452 are connected to the outer surface conductor 60. As described above, as a result of the ferrite substrate 20 being provided with the first recess 211 and the second recess 212, the connection area between the outer surface conductor 60 and the wiring conductor 421, and the connection area between the outer surface conductor 60 and the wiring conductor 422 are respectively increased. Accordingly, in the case where the grounding of the electronic components 51 and is implemented by the terminal conductors 411 and 412, the stability of the connection between the outer surface conductor 60 as a shield and the terminal conductors 411, 412 as the ground is improved. In addition, a stable ground is able to be achieved for the electronic components 51 and 52.

Further, in the above structure, since the conductors to be wired to the ground and the outer surface conductor, that is, the wiring conductors 421, 422, 451, and 452 are not disposed in the magnetic material layers 21 and 22, no parasitic inductance is generated and the ground is stabilized.

Further, as illustrated in FIG. 1, the first recess 211 and the second recess 212 have a depth that does not overlap the winding-shaped coil conductor of the coil 401 in the thickness direction of the ferrite substrate 20. This makes it possible to decrease or prevent a reduction in size of the cavity at the center of the coil 401, and to decrease or prevent the reduction in width of the coil conductor. Accordingly, it is possible to reduce or prevent the deterioration in characteristics of the coil 401. In other words, excellent coil characteristics are able to be achieved in the ferrite substrate 20 which is small in size.

As described above, by using the structure of this preferred embodiment, since the ground of the electronic components 51 and 52 is stabilized and the characteristics of the coil 401 are not deteriorated, the ferrite substrate module 10 achieves excellent electrical characteristics despite the ferrite substrate module 10 being small in size.

It is preferable that the wiring conductors 421, 422, 451, and 452 include Ag as a main ingredient. With this, the conductivity of the wiring conductors 421, 422, 451, and 452 is improved, and the ground is able to be more stabilized.

In addition, a coefficient of linear expansion α1 of the magnetic material layers 21 and 22 is preferably larger than a coefficient of linear expansion α2 of the nonmagnetic material layers 24 and 25 (α1>α2). With this, the ferrite substrate 20 achieves high bending strength, and the reliability is improved.

Further, in the wiring conductors 421, 422, 451, and 452, an additive to adjust a coefficient of linear expansion of each of the wiring conductors 421, 422, 451, and 452 may be added to Ag as the main ingredient. For example, ferrite powder may be added as an additive. This makes the coefficient of linear expansion of the wiring conductors 421, 422, 451, and 452 approach the coefficient of linear expansion α1 of the magnetic material layers 21, 22 and the coefficient of linear expansion α2 of the nonmagnetic material layers 24, 25. As a result, cracks of the magnetic material layers 21, 22 or the nonmagnetic material layers 24, 25 are able to be reduced or prevented in the vicinity of the wiring conductors 421, 422, 451 and 452, and the reliability of the ferrite substrate 20 is improved. In a case where the additive for adjusting the coefficient of linear expansion is added at least to an end portion of each of the wiring conductors 421, 422, 451, and 452 that is exposed to the recess or the side surface, at least the above-mentioned effect is able to be obtained. Further, since a coefficient of linear expansion of Ag is larger than the coefficient of linear expansion α1 of the magnetic material layers 21, 22 and the coefficient of linear expansion α2 of the nonmagnetic material layers 24, 25, it is sufficient that the additive to adjust the coefficient of linear expansion is a material having a coefficient of linear expansion equal to or lower than the coefficient of linear expansion α1 of the magnetic material layers 21, 22 and the coefficient of linear expansion α2 of the nonmagnetic material layers 24, 25.

The ferrite substrate module 10 having the above-discussed structure is applied to a circuit as illustrated in FIG. 3. As illustrated in FIG. 3, the ferrite substrate module 10 includes an input terminal PIN, an output terminal POUT, a ground terminal PGND, a control IC 91, an input capacitor 92, an inductor (choke coil) 93, and an output capacitor 94.

An input end of the control IC 91 is connected to the input terminal PIN. The input capacitor 92 is connected between the input terminal PIN and the ground terminal PGND. The inductor 93 is connected to an output end of the control IC 91, and is also connected to the output terminal POUT. The output capacitor 94 is connected between the output terminal POUT and the ground terminal PGND. The ground terminal PGND is connected to an external ground as a reference potential.

With this configuration, the ferrite substrate module 10 causes an input voltage Vin given to the input terminal PIN to be outputted from the output terminal POUT as an output voltage Vout, using switching control performed by the control IC 91. In other words, the ferrite substrate module 10 defines and functions as a step-down DC-DC converter.

Then, the structure illustrated in FIG. 1 and FIG. 2 is applied to the ferrite substrate module 10.

In this case, the electronic component 51 in FIG. 1 implements the control IC 91 in FIG. 3, the electronic component in FIG. 1 implements the input capacitor 92 and the output capacitor 94 in FIG. 3, and the coil 401 in FIG. 1 implements the inductor 93 in FIG. 3. Then, due to the improvement in stability of the connection between the outer surface conductor 60 shielding the above elements and the ground terminal PGND, it is possible to define the DC-DC converter while suppressing noise.

Since the wiring conductors 421, 422, 451, and 452 are not disposed in the magnetic material layers 21 and 22, no parasitic inductance is generated and the ground is stabilized. As a result, operation of the control IC 91 is stabilized, the ground of the input capacitor 92 and the output capacitor 94 is stabilized, and the deterioration in characteristics of the coil 401 is reduced or prevented. Accordingly, the ferrite substrate module 10 is able to achieve a stable ground, and achieves a power supply circuit having desired output characteristics.

Although, in the present preferred embodiment, the step-down DC-DC converter is exemplified and indicated as the ferrite substrate module 10, the ferrite substrate module 10 is also applicable to a step-up DC-DC converter or a step-up/step-down DC-DC converter including at least the inductor 93 and the control IC 91. In addition, the ferrite substrate module 10 is also applicable to other electronic circuits including at least the inductor 93 and the control IC 91. For example, the ferrite substrate module 10 is also applicable to a communication circuit including a filter circuit (LC circuit), or the like.

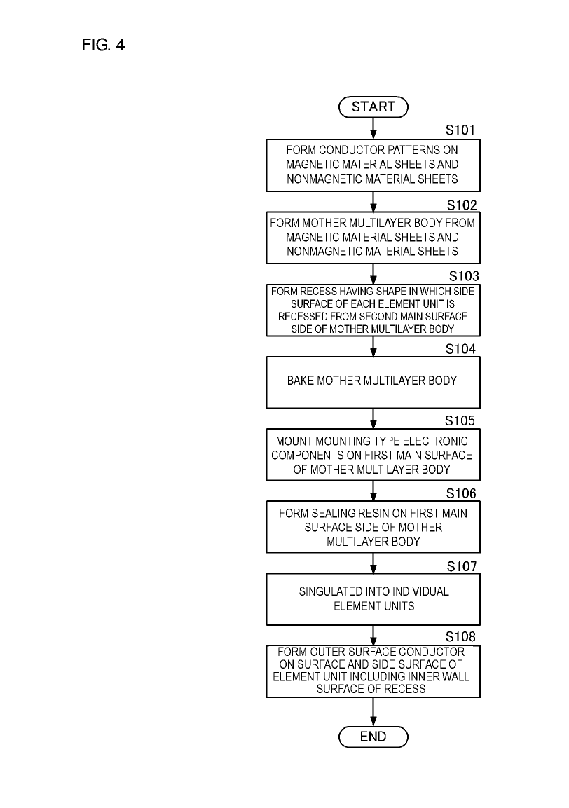

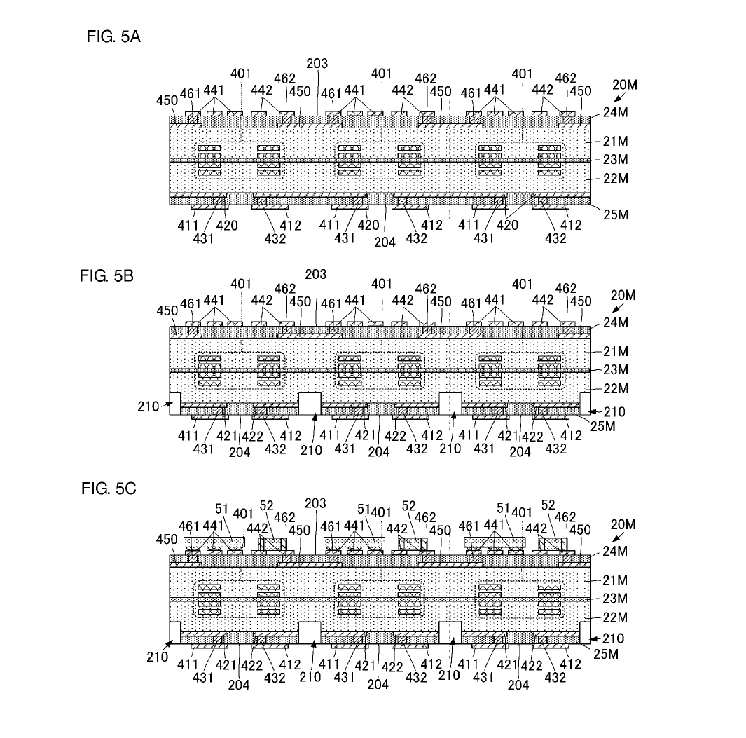

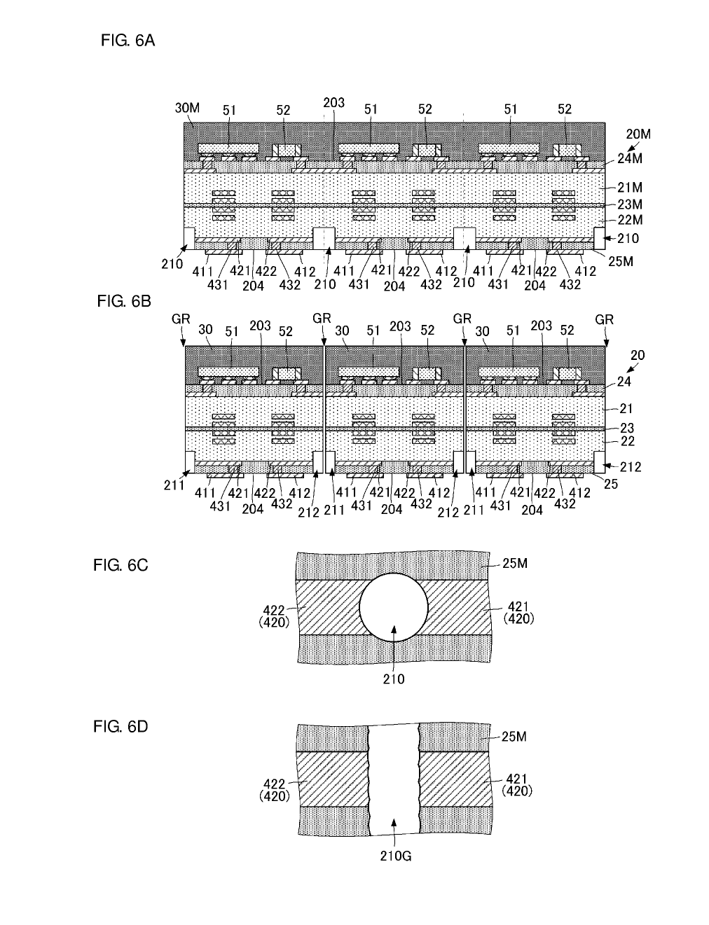

The ferrite substrate module 10 having the above-discussed structure is manufactured by a non-limiting example of a method described below. FIG. 4 is a flowchart illustrating an example manufacturing method for the ferrite substrate module according to the first preferred embodiment of the present invention. FIGS. 5A to 5C and FIGS. 6A and 6B are side cross-sectional views each illustrating a structure in a manufacturing process. FIGS. 6C and 6D are plan cross-sectional views in each of which a recess is enlarged and illustrated in a state of a mother multilayer body. Hereinafter, following the flowchart in FIG. 4, description will be given with reference to FIGS. 5A to 5C and FIGS. 6A to 6D.

First, as illustrated in FIG. 5A, respective conductor patterns are formed on a plurality of magnetic material sheets defining magnetic material layers 21M and 22M, and on a plurality of nonmagnetic material sheets defining nonmagnetic material layers 24M and 25M (S101). The plurality of magnetic material sheets defining the magnetic material layers 21M, 22M and the plurality of nonmagnetic material sheets defining the nonmagnetic material layers 24M, 25M are sheets (mother sheets) having a size capable of collectively forming a plurality of ferrite substrates 20. The conductor patterns are formed such that the plurality of ferrite substrates are arranged to define a final shape with respect to the mother sheet.

Coil conductors and interlayer connecting conductors defining the coil 401 are formed on the plurality of magnetic material sheets defining the magnetic material layers 21M and 22M. On the plurality of nonmagnetic material sheets defining the nonmagnetic material layer 24M, the component mounting land conductors 441 and 442, a wiring conductor 450, and the interlayer connecting conductors 461 and 462 are formed. On the plurality of nonmagnetic material sheets defining the nonmagnetic material layer 25M, the terminal conductors 411 and 412, a wiring conductor 420, and the interlayer connecting conductors 431 and 432 are formed. The wiring conductors 420 and 450 are each formed in a shape across a plurality of element units. The element unit refers to a section which will eventually become one ferrite substrate module 10 (ferrite substrate 20).

Next, as illustrated in FIG. 5A, the plurality of magnetic material sheets defining the magnetic material layers 21M and 22M, the plurality of nonmagnetic material sheets defining the nonmagnetic material layers 24M and 25M, and a nonmagnetic material sheet defining a nonmagnetic material layer 23M are laminated to form a mother multilayer body (S102).

Next, as illustrated in FIG. 5B, a recess 210 is formed having a shape to recess a side surface of each element unit from a surface on the nonmagnetic material layer 25M side (second main surface) of a mother multilayer body 20M (S103). For example, the recess 210 having a cylindrical shape is formed in such a manner that a substantially central position between the coils 401 adjacent to each other in the mother multilayer body 20M is set as the center of the cylindrical shape. The recess 210 is formed by drilling or the like.

The recess 210 is so formed as to pass through the nonmagnetic material layer 25M and the wiring conductor 420, and to locate its bottom surface at a depth that does not reach the coil conductor pattern in the magnetic material layer 22M. At this time, as illustrated in FIG. 6C, the recess 210 is formed so as to divide the wiring conductor 420. Thus, the wiring conductors 421 and 422 are exposed to an inner wall surface of the recess 210.

Next, the mother multilayer body 20M is baked (S104). Subsequently, as illustrated in FIG. 5C, the electronic components 51 and 52 are mounted on the first main surface 203 of the baked mother multilayer body 20M. The electronic component 51 is mounted on the component mounting land conductor 441, and the electronic component 52 is mounted on the component mounting land conductor 442.

Next, as illustrated in FIG. 6A, the sealing resin 30 is formed on the first main surface 203 side of the mother multilayer body 20M (S106).

Next, as illustrated in FIG. 6B, grooves GR to divide the mother multilayer body 20M into individual element units are formed in the mother multilayer body 20M, and then the mother multilayer body 20M is singulated into the plurality of element units (here, each element unit corresponds to the ferrite substrate module 10 in which the outer surface conductor 60 is not formed) (S107). Thus, the recesses 211 and 212 for each ferrite substrate modules 10 are formed.

Next, the outer surface conductor 60 is formed on the plurality of element units (S108). At this time, the outer surface conductor 60 is also formed on the inner wall surfaces 221 and 222 of the recesses 211 and 212. The outer surface conductor 60 is formed by, for example, a sputtering method.

By using the manufacturing method as discussed above, it is possible to manufacture the ferrite substrate module 10 of the above-described structure.

Note that the recess 210 is not limited to a cylindrical shape, and a groove 210G formed in a shape in which a plurality of cylindrical shapes is continuously connected, as illustrated in FIG. 6D, may be used instead. In this case, an inner wall surface of the groove 210G becomes non-linear by making a distance between the centers of the adjacent cylindrical shapes larger than the radius of the cylindrical shape. This makes it possible to obtain the same action effect as in the case of the recess 210 and to stabilize the ground.

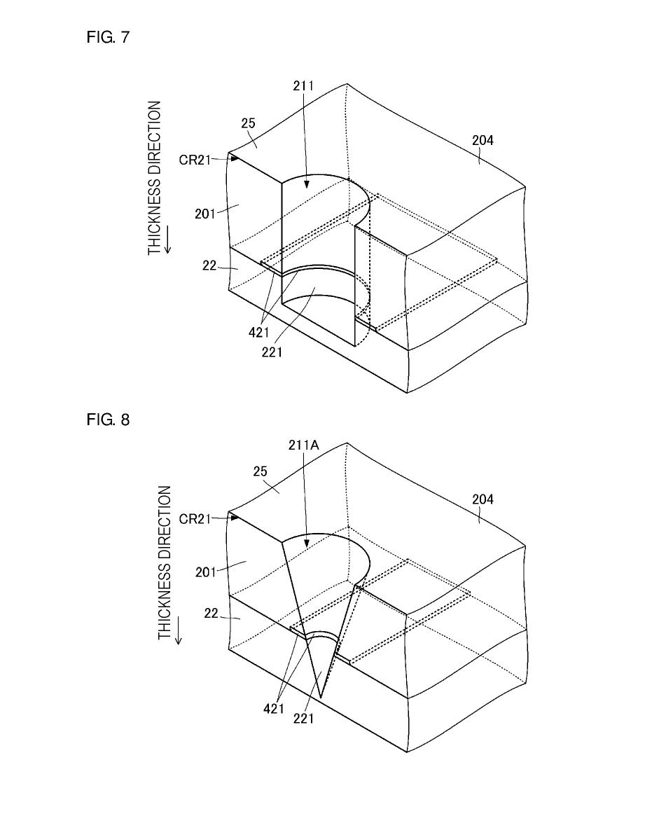

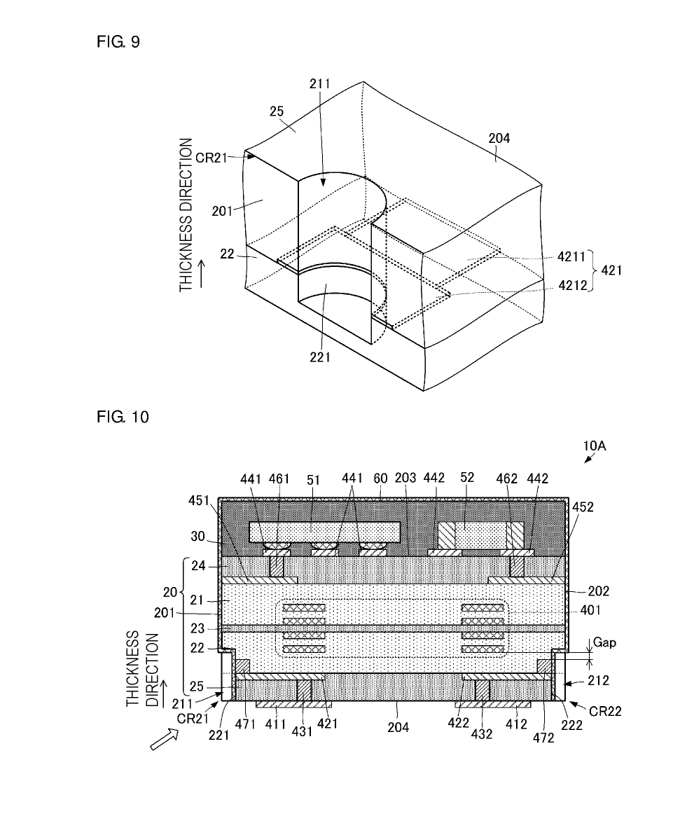

Further, the recess and a wiring conductor may have the following shapes and relationships. FIG. 7 is an enlarged perspective view illustrating a recess of a second example of a ferrite substrate module according to a preferred embodiment of the present invention. FIG. 8 is an enlarged perspective view illustrating a recess of a third example of a ferrite substrate module according to a preferred embodiment of the present invention. FIG. 9 is an enlarged perspective view illustrating a recess of the fourth example of the ferrite substrate module according to a preferred embodiment of the present invention. Although FIG. 7, FIG. 8, and FIG. 9 each illustrate only a first recess, a second recess has the same structure as the first recess. Therefore, only the first recess will be described below.

In the second example illustrated in FIG. 7, the width of the wiring conductor 421 is longer than the diameter of the first recess 211. Accordingly, an end surface of the wiring conductor 421 is exposed to the inner wall surface 221 of the first recess 211 and the first side surface 201 of the ferrite substrate 20. Also with this structure, it is possible to increase the connection area between the wiring conductor 421 and the outer surface conductor 60 (not illustrated).

In the third example illustrated in FIG. 8, a first recess 211A is a conical hole. In this case, the first recess 211A is formed by irradiation of a laser beam or the like. Also with this structure, it is possible to increase the connection area between the wiring conductor 421 and the outer surface conductor 60 (not illustrated). Although, in FIG. 8, the end surface of the wiring conductor 421 is exposed to the inner wall surface 221 of the first recess 211A and the first side surface 201 of the ferrite substrate 20, it may be exposed only to the inner wall surface 221 of the first recess 211A.

In the fourth example illustrated in FIG. 9, the wiring conductor 421 includes a first portion 4211 and a second portion 4212. The first portion 4211 and the second portion 4212 are connected to each other; one end side of the wiring conductor 421 in an extending direction thereof is the first portion 4211, and the other end side thereof is the second portion 4212. The first portion 4211 is connected to the terminal conductor 411 (see FIG. 1) with the interlayer connecting conductor 431 interposed therebetween (see FIG. 1). The second portion 4212 is exposed to the inner wall surface 221 of the first recess 211.

The first portion 4211 and the second portion 4212 differ from each other in terms of the composition of the materials. Specifically, the first portion 4211 contains Ag as a main ingredient, and unlike the second portion 4212, no additive is added. In the second portion 4212, an additive is added to Ag, which is a main ingredient. This additive functions to reduce the ductility of the second portion 4212 as compared with the first portion 4211, and is, for example, a material which functions to delay the sintering of Ag (a material having a higher melting point than Ag); Al₂O₃ can be cited as an example thereof.

With this structure, the second portion 4212 reduces or prevents necking as compared with the first portion 4211. Therefore, the cutting property of the wiring conductor 421 at the time of forming the first recess 211 is improved, and the dividing property at the time of dividing the mother multilayer body into individual element units is improved as well.

Note that the shapes of the recesses and the shapes of the wiring conductors in FIGS. 7, 8, and 9 may be combined and applied as desired. Further, the inner wall surface of the recess is not limited to a shape being curved in a plan view, and may be a shape being bent in a plan view (a shape of sides of a polygon).

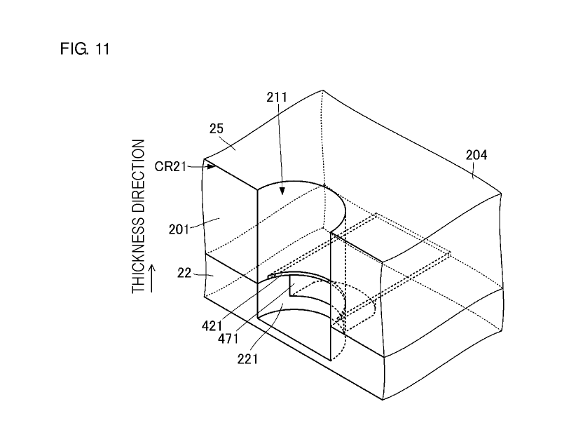

Next, a ferrite substrate module according to a second preferred embodiment of the present invention will be described with reference to the accompanying drawings. FIG. 10 is a side cross-sectional view illustrating a schematic configuration of a ferrite substrate module according to the second preferred embodiment of the present invention. FIG. 11 is an enlarged perspective view of a recess of the ferrite substrate module according to the second preferred embodiment of the present invention.

A ferrite substrate module 10A according to the second preferred embodiment is different from the ferrite substrate module 10 according to the first preferred embodiment in that wiring auxiliary conductors 471 and 472 are added. Other configurations of the ferrite substrate module 10A are similar to those of the ferrite substrate module 10, and description of the same elements will be omitted.

The wiring auxiliary conductor 471 is located at an end portion of a wiring conductor 421 on the side exposed to a first recess 211, and is connected to the wiring conductor 421. The wiring auxiliary conductor 471 has a columnar shape having a length in the thickness direction. An exposed surface of the wiring auxiliary conductor 471 to the first recess 211 is a non-linear surface (curved surface) in a plan view.

With this structure, an outer surface conductor 60 located on an inner wall surface 221 of the first recess 211 is connected to the wiring conductor 421 and the wiring auxiliary conductor 471. With this, a connection area with the outer surface conductor 60 at a position of the inner wall surface 221 becomes large in comparison with a case in which only the wiring conductor 421 is connected to the outer surface conductor 60, so that the ground is able to be further stabilized.

The wiring auxiliary conductor 472 is located at an end portion of a wiring conductor 422 on the side exposed to a second recess 212, and is connected to the wiring conductor 422. The wiring auxiliary conductor 472 has a columnar shape having a length in the thickness direction. An exposed surface of the wiring auxiliary conductor 472 to the second recess 212 is a non-linear surface (curved surface) in a plan view.

With this structure, the outer surface conductor 60 located on an inner wall surface 222 of the second recess 212 is connected to the wiring conductor 422 and the wiring auxiliary conductor 472. With this, a connection area with the outer surface conductor 60 at a position of the inner wall surface 222 becomes large in comparison with a case in which only the wiring conductor 422 is connected to the outer surface conductor 60, so that the ground is able to be further stabilized.

In the thickness direction of the ferrite substrate 20, an end surface of the wiring auxiliary conductor 471 on the opposite side to an end surface thereof making contact with the wiring conductor 421 is disposed closer to a nonmagnetic material layer 25 side than a surface on the nonmagnetic material layer 25 side of a coil conductor closest to the nonmagnetic material layer among a plurality of coil conductors defining a coil 401. Likewise, in the thickness direction of the ferrite substrate 20, an end surface of the wiring auxiliary conductor 472 on the opposite side to an end surface thereof making contact with the wiring conductor 422 is disposed closer to the nonmagnetic material layer 25 side than the surface on the nonmagnetic material layer 25 side of the coil conductor closest to the nonmagnetic material layer 25 among the plurality of coil conductors defining the coil 401. That is, Gap illustrated in FIG. 10 is larger than 0.

With this structure, a cavity at the center of the coil conductor defining the coil 401 is able to be enlarged, and the coil characteristics are able to be improved. In other words, it is possible to reduce or prevent the deterioration in the characteristics of the coil 401 due to the formation of the wiring auxiliary conductors 471 and 472.

It is preferable that the wiring auxiliary conductors 471 and 472 contain Ag as a main ingredient. Further, it is more preferable that the wiring auxiliary conductors 471 and 472 contain Ag as a main ingredient, and allow an additive which lowers the ductility of the wiring auxiliary conductors 471 and 472 to be added. As a result, the ground is further stabilized, and the cutting property and the dividing property of the wiring auxiliary conductors 471 and 472 are improved.

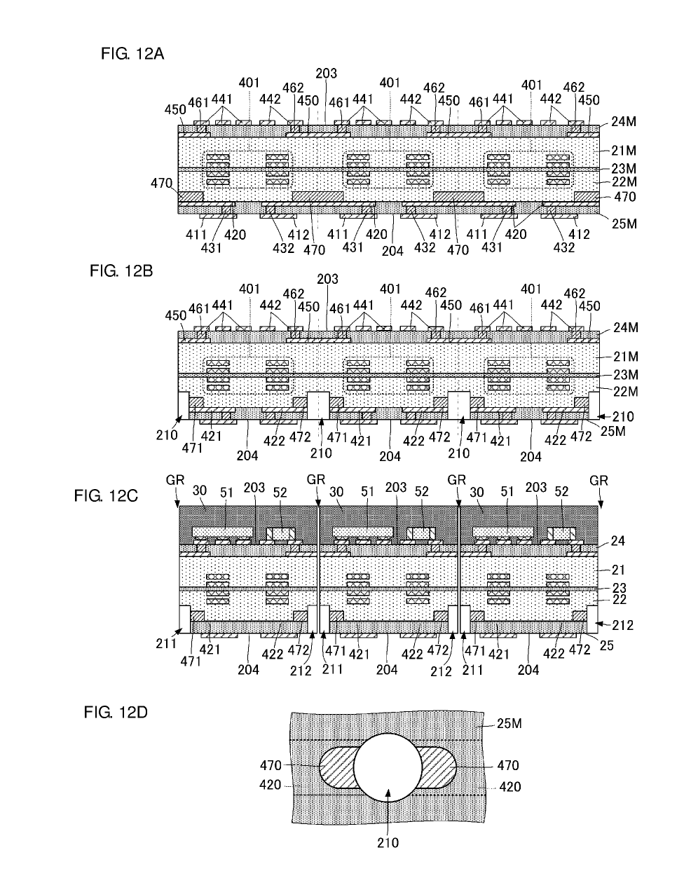

The ferrite substrate module 10A having the above-discussed structure is manufactured by a non-limiting example of a method described below. FIGS. 12A, 12B and 12C are side cross-sectional views each illustrating a structure in a manufacturing process. FIG. 12D is a plan cross-sectional view in which a recess is enlarged and illustrated in a state of a mother multilayer body. The basic manufacturing flow of the ferrite substrate module 10A is similar to the manufacturing flow of the ferrite substrate module 10 according to the first preferred embodiment, and description of the same sections will be omitted.

As illustrated in FIG. 12A, a wiring auxiliary conductor 470 is formed on a plurality of magnetic material sheets defining a magnetic material layer 22M. The wiring auxiliary conductor 470 is formed with a predetermined depth from a contact surface of the magnetic material layer 22M with respect to a nonmagnetic material layer 25M. The wiring auxiliary conductor 470 is formed in a shape across element units adjacent to each other.

As illustrated in FIG. 12B, a recess 210 is formed having a shape to recess a side surface of each element unit from a surface on the nonmagnetic material layer 25M side (second main surface) of a mother multilayer body 20M. The recess 210 is formed to extend through the nonmagnetic material layer 25M, a wiring conductor 420 and the wiring auxiliary conductor 470, and to arrange its bottom surface at a depth that does not reach the coil conductor pattern in the magnetic material layer 22M. At this time, as illustrated in FIG. 12D, the recess 210 is so formed as to divide the wiring conductor 420 and the wiring auxiliary conductor 470. Thus, the wiring conductors 421 and 422 and the wiring auxiliary conductors 471 and 472 are exposed to an inner wall surface of the recess 210.

Next, as illustrated in FIG. 12C, grooves GR to divide the mother multilayer body 20M into individual element units are formed in the mother multilayer body 20M, and then the mother multilayer body 20M is singulated into the plurality of element units.

By using the manufacturing method as discussed above, it is possible to manufacture the ferrite substrate module 10A of the above-described structure.

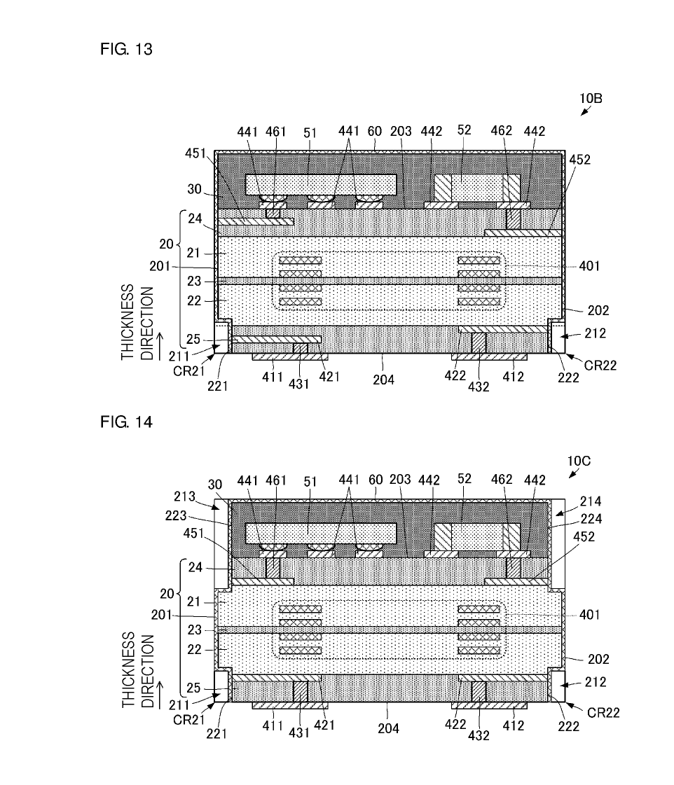

Next, a ferrite substrate module according to a third preferred embodiment of the present invention will be described with reference to the accompanying drawings. FIG. 13 is a side cross-sectional view illustrating a schematic configuration of the ferrite substrate module according to the third preferred embodiment of the present invention.

As illustrated in FIG. 13, a ferrite substrate module 10B according to the third preferred embodiment differs from the ferrite substrate module 10 according to the first preferred embodiment in that a wiring conductor 421 and a wiring conductor 451 are disposed in different positions. Other configurations of the ferrite substrate module 10B are similar to those of the ferrite substrate module 10, and description of the same elements will be omitted.

The wiring conductor 421 is disposed at an intermediate position in the thickness direction of a nonmagnetic material layer 25. The wiring conductor 451 is disposed at an intermediate position in the thickness direction of a nonmagnetic material layer 24. Also with this structure, stabilization of the ground is able to be achieved.

Note that a wiring conductor 422 may be disposed at an intermediate position in the thickness direction of the nonmagnetic material layer 25, and a wiring conductor 452 may be disposed at an intermediate position in the thickness direction of the nonmagnetic material layer 24. However, as in the case of the ferrite substrate module 10 according to the first preferred embodiment, it is preferable that each wiring conductor be disposed at an interface between the nonmagnetic material layer and the magnetic material layer. With this structure, stress due to a difference in coefficient of linear expansion between the nonmagnetic material layer and the magnetic material layer is alleviated by the ductility of the wiring conductor. As a result, cracks in the nonmagnetic material layer are reduced or prevented.

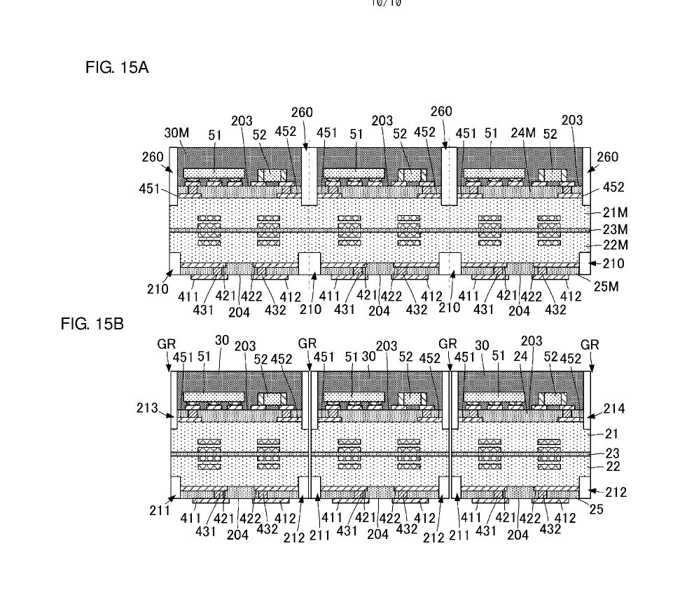

Next, a ferrite substrate module according to a fourth preferred embodiment of the present invention will be described with reference to the accompanying drawings. FIG. 14 is a side cross-sectional view illustrating a schematic configuration of a ferrite substrate module according to the fourth preferred embodiment of the present invention.

As illustrated in FIG. 14, a ferrite substrate module 10C according to the fourth preferred embodiment is different from the ferrite substrate module 10 according to the first preferred embodiment in that a recess is also provided at the side of a nonmagnetic material layer 24. Other configurations of the ferrite substrate module 10C are similar to those of the ferrite substrate module 10, and description of the same elements will be omitted.

A ferrite substrate 20 and a sealing resin 30 are provided with a third recess 213 and a fourth recess 214. The third recess 213 and the fourth recess 214 correspond to a “first main surface side recess”.

As illustrated in FIG. 14, the third recess 213 is recessed from a side surface of the sealing resin 30 (a surface flush with a first side surface 201) and from the first side surface 201 of the ferrite substrate 20. The third recess 213 extends through the sealing resin 30 in the thickness direction from a top surface of the sealing resin 30 (a surface on the opposite side to a surface in contact with the ferrite substrate 20), and is recessed by a predetermined depth from a first main surface 203 of the ferrite substrate 20 (a formation surface of component mounting land conductors 441 and 442). More specifically, the third recess 213 also passes through the nonmagnetic material layer 24 in the thickness direction, and a bottom surface thereof perpendicular to the thickness direction reaches a magnetic material layer 21.

An inner wall surface 223 of the third recess 213 perpendicular to the first main surface 203 is non-linear. In other words, the third recess 213 is open to the first main surface 203 and the first side surface 201 of the ferrite substrate 20, and has the non-linear inner wall surface 223 when viewed in a direction perpendicular to the first main surface. Specifically, similarly to an inner wall surface 221 of a first recess 211, the inner wall surface 223 is a curved surface having a predetermined diameter.

The fourth recess 214 has a shape being recessed from a side surface of the sealing resin 30 (a surface flush with a second side surface 202) and from the second side surface 202 of the ferrite substrate 20. The shape of the fourth recess 214 is similar to that of the third recess 213.

An inner wall surface 224 of the fourth recess 214 perpendicular to the first main surface 203 is non-linear. In other words, the fourth recess 214 is open to the first main surface 203 and the second side surface 202 of the ferrite substrate 20, and includes the non-linear inner wall surface 224 when viewed in the direction perpendicular to the first main surface. Specifically, similarly to an inner wall surface 222 of a second recess 212, the inner wall surface 224 is a curved surface having a predetermined diameter.

Further, it is preferable that, in the thickness direction, the position of a bottom surface perpendicular to the thickness direction of each of the third recess 213 and the fourth recess 214 be a position closer to the nonmagnetic material layer 24 than the position of a surface on the nonmagnetic material layer 24 side of the coil conductor closest to the nonmagnetic material layer 24 among the coil conductors forming a coil 401. With this structure, a cavity at the center of the coil conductor defining the coil 401 is able to be enlarged, and the coil characteristics are improved.

With the above-discussed structure, it is possible to increase the connection area between a wiring conductor 451 and an outer surface conductor 60 and the connection area between a wiring conductor 452 and the outer surface conductor 60, and to further stabilize the ground for the electronic components 51 and 52.

Note that, similarly to the wiring conductors 421 and 422, the wiring conductors 451 and 452 each may be defined by two portions having different compositions. The wiring conductor 451 includes a third portion on a side connected to an interlayer connecting conductor 461 and a fourth portion on a side exposed to the third recess 213. Likewise, the wiring conductor 452 includes a third portion on a side connected to an interlayer connecting conductor 462 and a fourth portion on a side exposed to the fourth recess 214. The third portion has the same composition as the first portion, and the fourth portion has the same composition as the second portion. This makes it possible to improve the dividing property of the ferrite substrate 20 on the nonmagnetic material layer 24 side as well.

Similarly to the wiring auxiliary conductors 471 and 472 for the wiring conductors 421 and 422, wiring auxiliary conductors may be disposed for the wiring conductors 451 and 452.

The ferrite substrate module 10B having the above-discussed structure is manufactured by a method described below. FIGS. 15A and 15B are side cross-sectional views each illustrating a structure in a manufacturing process. Note that a manufacturing flow of the ferrite substrate module 10B from the start to a process in which a sealing resin 30M is formed is similar to the manufacturing flow of the ferrite substrate module 10 according to the first preferred embodiment, and description of the same sections will be omitted.

As illustrated in FIG. 15A, a recess 210 is structured to recess a side surface of each element unit from a surface on a nonmagnetic material layer 25M side (second main surface) of a mother multilayer body 20M. The recess 210 extends through the nonmagnetic material layer 25M and a wiring conductor 420 (see FIGS. 5A to 5C), and has a bottom surface located at a depth that does not reach a coil conductor pattern in a magnetic material layer 22M.

Further, as illustrated in FIG. 15A, a recess 260 is structured to recess a side surface of each element unit from a surface of the sealing resin 30M on the opposite side to a surface thereof making contact with the mother multilayer body 20M. The recess 260 extends through the sealing resin 30M, a nonmagnetic material layer 24M and a wiring conductor 450 (see FIGS. 5A to 5C), and has a bottom surface located at a depth that does not reach a coil conductor pattern in a magnetic material layer 21M.

Next, as illustrated in FIG. 15B, grooves GR to divide the mother multilayer body 20M into individual element units are formed in the mother multilayer body 20M after the sealing resin 30M being formed thereupon, and then the mother multilayer body 20M after the sealing resin 30M being formed thereupon is singulated into the plurality of element units. Thereafter, the outer surface conductor 60 is formed so as to include the inner wall surface 221 of the first recess 211, the inner wall surface 222 of the second recess 212, the inner wall surface 223 of the third recess 213, and an inner wall surface 224 of the fourth recess 214.

By using the manufacturing method as discussed above, it is possible to manufacture the ferrite substrate module 10B of the above-described structure.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A substrate module comprising:
a multilayer substrate including a first main surface and a second main surface opposing each other, and a side surface connecting the first main surface and the second main surface, and including a component mounting land conductor on the first main surface and a terminal conductor on the second main surface;
an electronic component mounted on the component mounting land conductor;
an outer surface conductor covering a first main surface side and the side surface of the multilayer substrate;
a magnetic material layer in which a coil is provided; and
a first nonmagnetic material layer and a second nonmagnetic material layer that sandwich the magnetic material layer between the first nonmagnetic material layer and the second nonmagnetic material layer; wherein
a surface of the first nonmagnetic material layer on an opposite side to the magnetic material layer is the first main surface, and a surface of the second nonmagnetic material layer on an opposite side to the magnetic material layer is the second main surface;
the multilayer substrate further includes a second main surface side recess that is open to the second main surface and the side surface of the multilayer substrate and includes a non-linear inner wall surface when viewed in a direction orthogonal to the second main surface, and a second main surface side wiring conductor is in contact with the second nonmagnetic material layer, connected to the terminal conductor, and exposed to the inner wall surface of the second main surface side recess; and
the outer surface conductor is provided on the inner wall surface of the second main surface side recess, and is connected to the second main surface side wiring conductor.

2. The substrate module according to claim 1, further comprising:
a first main surface side recess that is open to the first main surface and the side surface of the multilayer substrate and includes a non-linear inner wall surface when viewed in a direction orthogonal to the first main surface; and
a first main surface side wiring conductor that is in contact with the first nonmagnetic material layer, connected to the component mounting land conductor, and exposed to the inner wall surface of the first main surface side recess; wherein
the outer surface conductor is provided on the inner wall surface of the first main surface side recess, and is connected to the first main surface side wiring conductor.

3. The substrate module according to claim 1, wherein a coefficient of linear expansion of the second nonmagnetic material layer is smaller than a coefficient of linear expansion of the magnetic material layer.

4. The substrate module according to claim 1, wherein the second main surface side wiring conductor is disposed at an interface between the second nonmagnetic material layer and the magnetic material layer.

5. The substrate module according to claim 1, further comprising:
a wiring auxiliary conductor that is connected to an end portion of the second main surface side wiring conductor exposed to the inner wall surface, and has a predetermined length in a thickness direction of the multilayer substrate.

6. The substrate module according to claim 1, wherein
the second main surface side wiring conductor includes a first portion including an end portion on a side connected to the terminal conductor, and a second portion exposed to the inner wall surface of the second main surface side recess; and
the second portion is less ductile than the first portion.

7. The substrate module according to claim 6, wherein
the first portion is made of a material containing Ag as a main ingredient; and
the second portion is made of a material of Ag as a main ingredient and an additive.

8. The substrate module according to claim 7, wherein a coefficient of linear expansion of the additive is equal to or smaller than a coefficient of linear expansion of a material of the multilayer substrate.

9. The substrate module according to claim 7, wherein a melting point of the additive is higher than a melting point of the Ag.

10. A substrate module comprising:
a multilayer substrate including a first main surface and a second main surface opposing each other, and a side surface connecting the first main surface and the second main surface, and including a component mounting land conductor on the first main surface and a terminal conductor on the second main surface;
an electronic component mounted on the component mounting land conductor;
an outer surface conductor covering the first main surface side and the side surface of the multilayer substrate;
a magnetic material layer in which a coil is provided; and
a first nonmagnetic material layer and a second nonmagnetic material layer that sandwich the magnetic material layer between the first nonmagnetic material layer and the second nonmagnetic material layer; wherein
a surface of the first nonmagnetic material layer on an opposite side to the magnetic material layer is the first main surface, and a surface of the second nonmagnetic material layer on an opposite side to the magnetic material layer is the second main surface;
the multilayer substrate further includes a first main surface side recess that is open to the first main surface and the side surface of the multilayer substrate and includes a non-linear inner wall surface when viewed in a direction orthogonal to the first main surface, and a first main surface side wiring conductor that is in contact with the first nonmagnetic material layer, connected to the component mounting land conductor, and exposed to the inner wall surface of the first main surface side recess; and
the outer surface conductor is provided on the inner wall surface of the first main surface side recess, and is connected to the first main surface side wiring conductor.

11. The substrate module according to claim 10, wherein a coefficient of linear expansion of the first nonmagnetic material layer is smaller than a coefficient of linear expansion of the magnetic material layer.

12. The substrate module according to claim 10, wherein the first main surface side wiring conductor is disposed at an interface between the first nonmagnetic material layer and the magnetic material layer.

13. The substrate module according to claim 10, further comprising:
a wiring auxiliary conductor that is connected to an end portion of the first main surface side wiring conductor exposed to the inner wall surface, and has a predetermined length in a thickness direction of the multilayer substrate.

14. The substrate module according to claim 10, wherein
the first main surface side wiring conductor includes a third portion including an end portion on a side connected to the component mounting land conductor, and a fourth portion exposed to the inner wall surface of the first main surface side recess; and
the fourth portion is less ductile than the third portion.

15. The substrate module according to claim 14, wherein
the third portion is made of a material containing Ag as a main ingredient; and
the fourth portion is made of a material of Ag as a main ingredient and an additive.

16. The substrate module according to claim 15, wherein a coefficient of linear expansion of the additive is equal to or smaller than a coefficient of linear expansion of a material of the multilayer substrate.

17. The substrate module according to claim 15, wherein a melting point of the additive is higher than a melting point of the Ag.

18. The substrate module according to claim 1, wherein the electronic component is a surface mount electronic component.

19. The substrate module according to claim 10, wherein the electronic component is a surface mount electronic component.
